(19) United States
(12) Patent Application Publication
(10) Pub. No.: US 2012/0188723 A1
(43) Pub. Date: Jul. 26, 2012

(54) HEAT DISSIPATION ASSEMBLY AND ELECTRONIC DEVICE WITH SAME

(75) Inventors: JIAN LIU, Shenzhen City (CN); JING ZHANG, Shenzhen City (CN)

(73) Assignees: FOXCONN TECHNOLOGY CO., LTD., Tu-Cheng (TW); FU ZHUN PRECISION INDUSTRY (SHEN ZHEN) CO., LTD., Shenzhen City (CN)

(21) Appl. No.: 13/274,533

(22) Filed: Oct. 17, 2011

(30) Foreign Application Priority Data
Jan. 26, 2011 (CN) 201110028234.3

(51) Int. Cl. H05K 7/20; F28F 9/00

(52) U.S. Cl. 361/720; 165/67

(57) ABSTRACT

A heat dissipation assembly comprises a heat conducting plate, a fixing assembly for securing the heat conducting plate on an electronic module, a back plate opposite to the heat conducting plate. The fixing assembly comprises a bolt, an elastic element coiled around the bolt, and a nut. The heat conducting plate defines a through hole thereon, and a flange is defined at one end of the bolt and received in the nut. The nut is sandwiched between the heat conducting plate and the back plate and is made of elastically plastic. The back plate comprises a hollow fixed leg defined thereon correspond to the through hole of the heat conducting plate. Two ends of the nut are respectively attached to the heat conducting plate and the electronic module by tension from the elastic element.

### BACKGROUND

1. Technical Field

The disclosure relates to heat dissipation assemblies and, more particularly, to an electronic device having a printed circuit board and a heat dissipation assembly mounting on the printed circuit board securely.

2. Description of Related Art

With the increasing development of computer technology, electronic components such as central processing units (CPUs) of computers are being made to operate at higher operational speeds and to have greater functional capabilities. When an electronic component operates at a high speed, it frequently generates large amounts of heat. The heat must be quickly removed from the electronic component to prevent it from becoming unstable or being damaged. Typically, the electronic component is mounted on a printed circuit board, and a heat sink is attached to an outer surface of the electronic component to absorb heat from the electronic component.

In order to keep the heat sink in intimate contact with the electronic component, one or more fasteners are used to secure the heat sink to the electronic component. A conventional fastener comprises a pin and a spring disposed around the pin. The pin has a head at an end thereof and a clamping portion at an opposite end thereof. The clamping portion has outer thread defined thereon. The clamping portion of the pin passes through the heat sink and screws into the printed circuit board. The spring is compressed between the head of the pin and the heat sink to provide an elastic force which urges the heat sink to intimately attach to the electronic component.

However, the elastic force from the spring can not be controlled. The printed circuit board is liable to twist under great elastic force applied by the fastener(s), the electrical connections of the printed circuit board may be fractured by the great elastic force, and communication between the printed circuit board and the electronic component may be significantly influenced.

What is needed, therefore, is a heat dissipation assembly and an electronic device having the same which can overcome the problems described above.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the several views.

FIG. 1 is an isometric view of an electronic device in accordance with an embodiment of the disclosure.

FIG. 2 is an exploded view of the electronic device of FIG. 1.

FIG. 3 is an isometric, enlarged view of a nut of the electronic device in FIG. 2.

FIG. 4 is an isometric view of the nut in FIG. 3, but showing the nut inverted.

FIG. 5 is an enlarged, cross-sectional view of part of the electronic device in FIG. 1, corresponding to line V-V thereof, and showing an assembled heat dissipation assembly aligning with a back plate via an electronic module.

FIG. 6 is similar to FIG. 5, but showing the assembled heat dissipation assembly cooperating with the back plate via the electronic module.

### DETAILED DESCRIPTION

The invention is susceptible of embodiments in many different forms. One or more of the embodiments are shown in the figures and will be described in detail herein, and include the preferred embodiment(s) of the invention. However, the present disclosure is to be considered as an exemplification of the principles of the invention, and is not intended to limit the broad aspects of the invention to the embodiments described and illustrated.

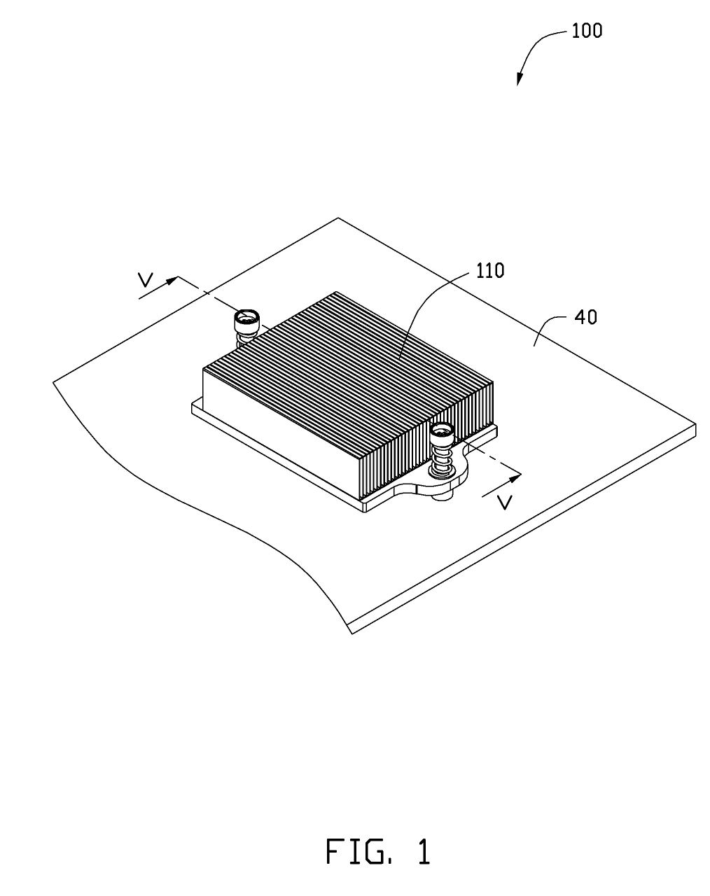

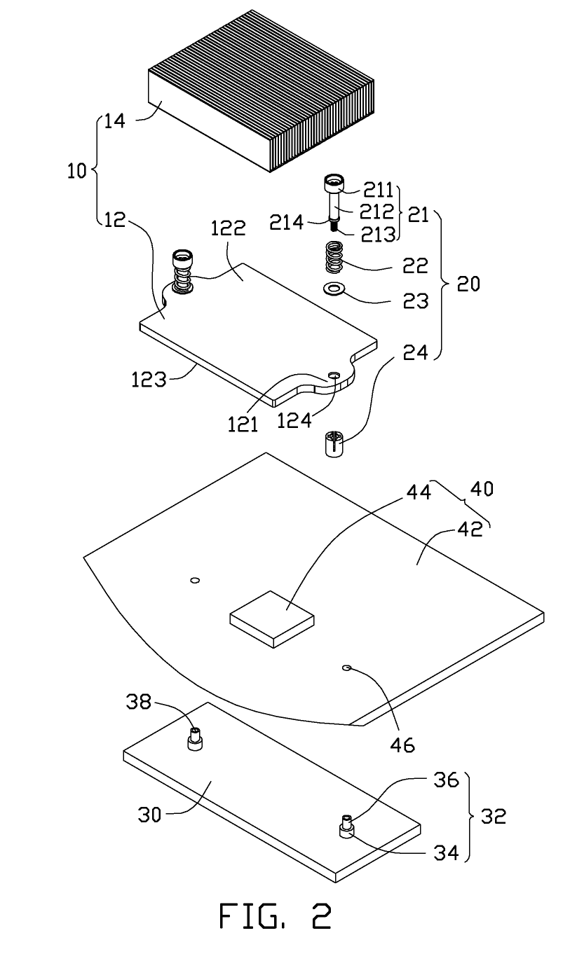

Referring to FIGS. 1 and 2, an electronic device 100 in accordance with an embodiment of the disclosure is shown. The electronic device 100 can be part of a computer. The electronic device 100 includes a heat dissipation assembly 110 and an electronic module 40. The heat dissipation assembly 110 is located on the electronic module 40 to dissipate heat generated by the electronic module 40 to ambient air. An enclosure of the computer which accommodates the electronic device 100 is omitted from the drawings.

The heat dissipation assembly 110 includes a heat dissipation device 10, a number of fixing assemblies 20 configured to secure the heat dissipation device 10 on the electronic module 40, and a back plate 30 placed under the bottom of the electronic module 40. In the present embodiment, there are two fixing assemblies 20. The heat dissipation device 10 is securely connected with the back plate 30 to sandwich the electronic module 40 therebetween.

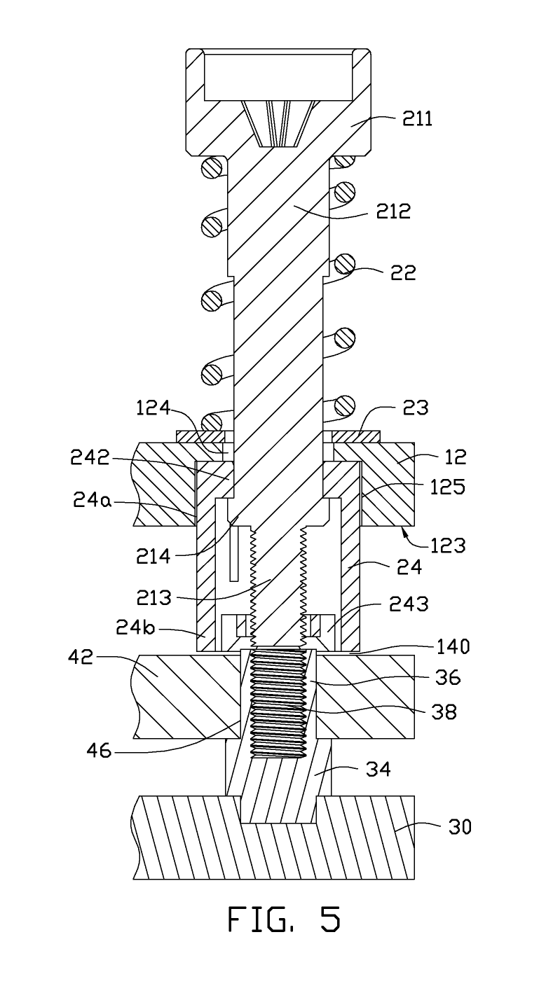

The heat dissipation device 10 includes a heat conducting plate 12, and a heat sink 14 mounted on the heat conducting plate 12. The heat conducting plate 12 has a top surface 122 and a bottom surface 123. The top surface 122 supports the heat sink 14, and the bottom surface 123 is thermally connected to the electronic module 40. The heat conducting plate 12 is rectangular, and at least two fastening portions 121 respectively extend horizontally outwardly from two opposite edges of the heat conducting plate 12. A through hole 124 is defined in an upper portion of each fastening portion 121. As shown in FIG. 5, a groove 125 is defined in a lower portion of each fastening portion 121, and below and in communication with a corresponding through hole 124. A diameter of the groove 125 is greater than a diameter of the through hole 124. Specifically, the through hole 124 and the groove 125 both have a cylindrical shape, and the through hole 124 is coaxial with the groove 125. It can be understood that, in alternative embodiments, the through hole 124 and the groove 125 may be have other shapes. The heat sink 14 firmly contacts to the top surface 122 of the heat conducting plate 12, to absorb heat gathered in the heat conducting plate 12 and dissipate the heat to ambient air.

Each fixing assembly 20 includes a bolt 21, an elastic element 22 coiled around the bolt 21, a gasket 23, and a nut 24. The bolt 21 includes a head portion 211, a main body 212 extending from the head portion 211, a connecting portion 213 located at one end of the main body 212 opposite to the head portion 211, and a flange 214 defined at the connection of the main body 212 and the connecting portion 213. The connecting portion 213 has outer screw thread defined thereon. The elastic element 22 is coiled around the main body 212 of the bolt 21, and sandwiched between the heat conducting plate 12 and the head portion 211 of the bolt 21.

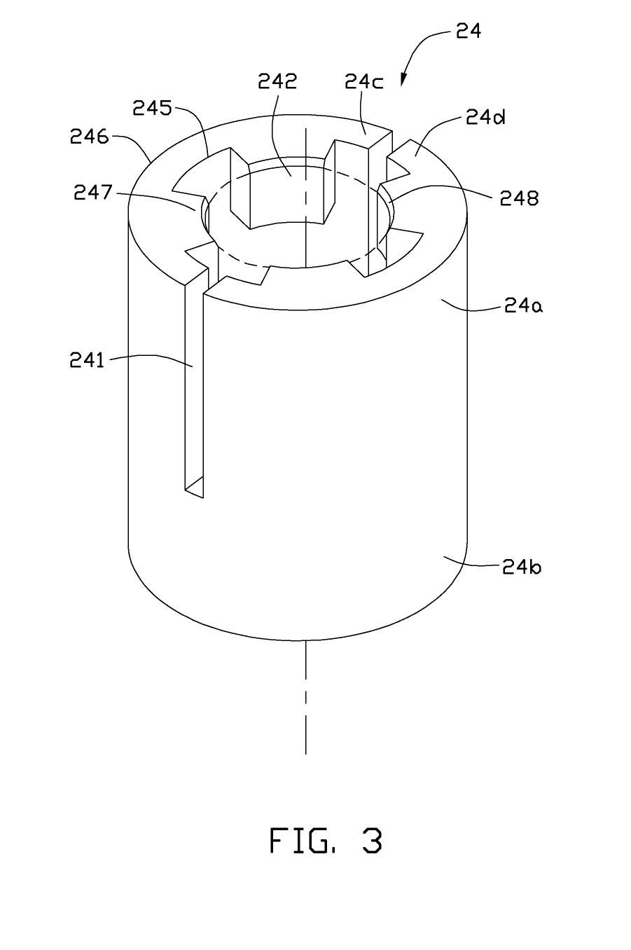

Referring also to FIG. 3, the nut 24 has a configuration of a cylinder. The nut 24 has an inner side surface 245 and an outer side surface 246. The nut 24 also defines an upper portion 24a and a lower portion 24b. The upper portion 24a of the nut 24 has two symmetrical elongated slots 241 defined therein, the slots 241 extending upwardly from the lower portion 24b of the nut 24. In such manner, the upper portion 24a of the nut 24 forms two claws 24c, 24d by the slots 241. The upper portion 24a of the nut 24 also forms a number of blocking pieces 242 perpendicularly extending radially inward from the inner side surface 245 of nut 24. The blocking pieces 242 are equally angularly spaced from each other around a circumference of the upper portion 24a. In the illustrated embodiment, there are four blocking pieces 242: two on each of the claws 24c, 24d. The blocking pieces 242 on the claw 24c are symmetrical to the blocking pieces 242 on the claw 24d across an imaginary plane (not shown) running between the two slots 241 of the nut 24. An inner surface of each blocking piece 242 which faces a center of the nut 24 is a segment of cylindrical face, and all the inner surfaces of the blocking pieces 242 cooperatively define an imaginary cylindrical surface (not labeled). A slope 248 is formed at the connection of the inner surface of each blocking piece 242 and a top surface 247 of the nut 24.

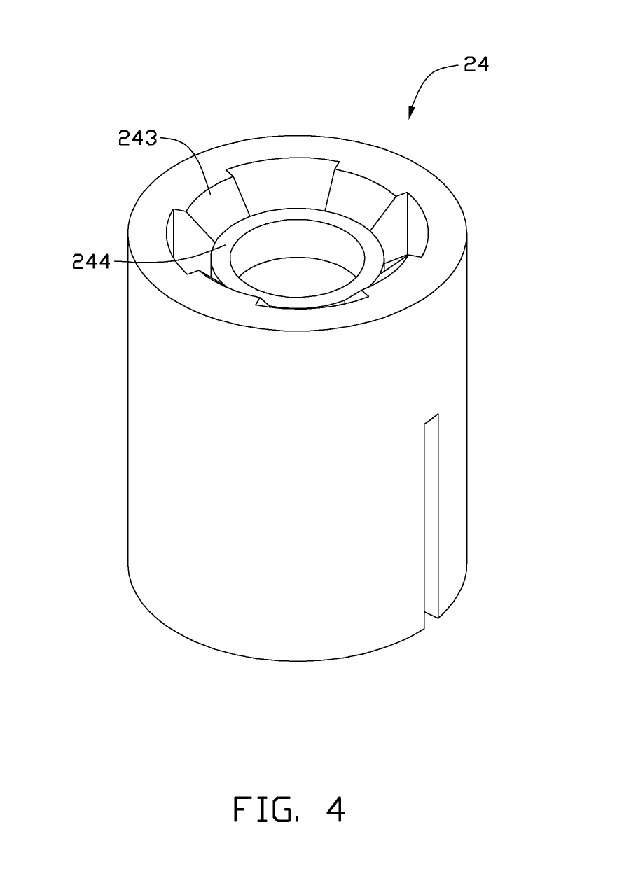

As shown in FIG. 4, the lower portion 24b of the nut 24 forms a number of connecting pieces 243 extending radially inwardly from the inner side surface 245 of the nut 24. A ring-shaped convex blocking tube 244 is received in the nut 24 and connecting with all the connecting pieces 243. In present embodiment, the nut 24 is made of elastically deformable plastic.

Referring back to FIG. 2, the back plate 30 has two cylindrical, hollow fixed legs 32 defined thereon. Each fixed leg 32 extends upwardly from a top surface of the back plate 30. Each fixed leg 32 has a bottom holding portion 34 connected to the back plate 30, and a top holding portion 36 extending upwardly from a top surface of the bottom holding portion 34. A diameter of the top holding portion 36 is smaller than that of the bottom holding portion 34. Each fixed leg 32 has a threaded hole 38 defined therein.

As shown in FIG. 2, the electronic module 40 includes a circuit board 42 and an electric element 44 located on the circuit board 42. The circuit board 42 has a number of fixing holes 46 defined therein and spaced from each other. The fixing holes 46 correspond to the through holes 124 of the heat conducting plate 12, and also correspond to the fixed legs 32 of the back plate 30. In the present embodiment, there are two fixing holes 46. A thickness of the circuit board 42 is smaller than a length of the top holding portion 36 of each fixed leg 32. The electric element 44 can for example be a CPU.

In alternative embodiments, the bolt 21 of each fixing assembly 20 may instead be another kind of connector. For example, the connecting portion 213 of the bolt 21 can be a pole with an elastic hook provided on its terminal, so that the connecting portion 213 of the bolt 21 can be fixed on the circuit board 42.

Referring to FIG. 5, portions of the assembled heat dissipation assembly 110 aligning with the back plate 30 via the electronic module 40 is shown. A gap 140 is formed between the nut 24 and the circuit board 42. This means that a distance from a bottom surface (not labeled) of the lower portion 24b of the nut 24 to the bottom surface 123 of the heat conducting plate 12 is slightly smaller than a height of the electric element 44 of the electronic module 40. A diameter of the head portion 211 of the bolt 21 of the corresponding fixing assembly 20 is greater than that of the through hole 124 defined in the heat conducting plate 12. A diameter of the main body 212 of the bolt 21 is greater than that of the connecting portion 213 and smaller than that of the head portion 211. A diameter of the flange 214 is smaller than that of the gasket 23 and smaller than that of the through hole 124 defined in the heat conducting plate 12, such that the flange 214 of the bolt 21 can freely pass through the gasket 23 and the heat conducting plate 12.

An outside diameter of the nut 24 is smaller than that of the groove 125 of the heat conducting plate 12, so that the upper portion 24a of the nut 24 can be received in the groove 125 of the heat conducting plate 12. An inside diameter of the nut 24 is greater than the diameter of the flange 214 of the bolt 21, and a diameter of the imaginary cylindrical surface of the nut 24 is smaller than that of the flange 214 of the bolt 21 and greater than that of the main body 212 of the bolt 21. Therefore the flange 214 of the bolt 21 can be moved upwardly and downwardly in the nut 24, and can also be stopped by the blocking pieces 242 of the nut 24. An inside diameter of the ring-shaped convex blocking tube 244 is smaller than the diameter of the flange 214 of the bolt 21, so that the bolt 21 can be stopped by the ring-shaped convex blocking tube 244 when the bolt 21 moves downwardly. A diameter of the corresponding fixing hole 46 is slightly greater than that of the top holding portion 36 of the corresponding fixed leg 32, and is smaller than that of the bottom holding portion 34 of the fixed leg 32.

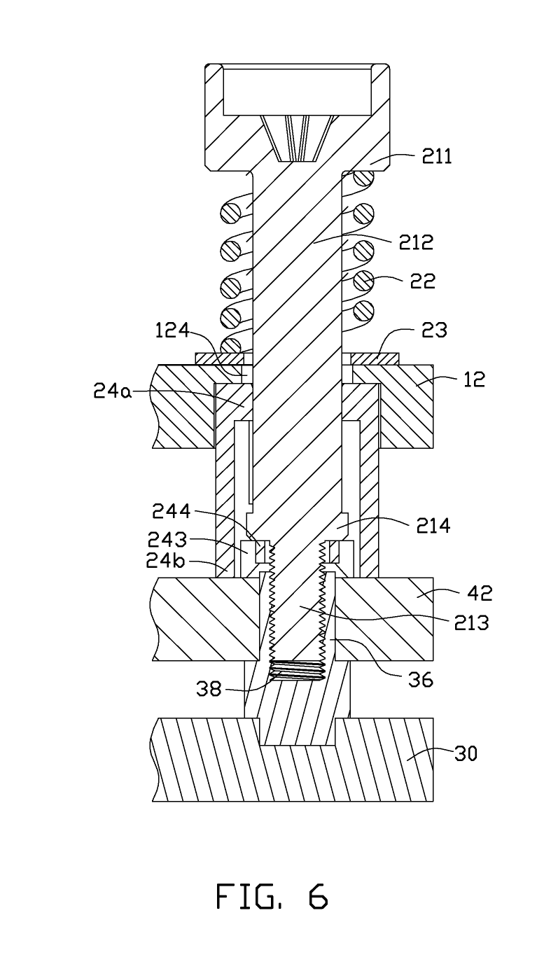

Referring to FIG. 6, a portion of the assembled electronic device 100 is shown. The connecting portion 213 passes through the ring-shaped convex blocking tube 244 to screw into the threaded hole 38 of the fixed leg 32, such that the elastic element 22 is compressed and the flange 214 of the bolt 21 contacts a top surface (not labeled) of the ring-shaped convex blocking tube 244. The heat conducting plate 12 is pushed downwardly relative to the circuit board 42 by the elastic element 22, and the lower portion 24b of the nut 24 contacts the circuit board 42 firmly with the gap 140 (shown in FIG. 5) disappearing. Therefore the heat conducting plate 12 further contacts the electric element 44 located on the circuit board 42 firmly, with the heat conducting plate 12 simultaneously being deformed slightly. Accordingly, heat from the electric element 44 can be quickly transferred to the heat sink 14 by passing through the heat conducting plate 12. The heat absorbed by the heat sink 14 is then dissipated to ambient air.

Referring to FIGS. 5 and 6, a method for assembling the heat dissipation assembly 110 is as follows: placing the upper portion 24a of the nut 24 into the corresponding groove 125 of the heat conducting plate 12; coiling the elastic element 22 and the gasket 23 around the main body 212 of the bolt 21 successively; causing the connecting portion 213 and the main body 212 of the bolt 21 to pass through the through hole 124 of the heat conducting plate 12, resulting in the elastic element 22 being sandwiched between the heat conducting plate 12 and the head portion 211 of the bolt 21; and pressing the bolt 21 until the elastic element 22 is compressed and the connecting portion 213 of the bolt 21 passes through the nut 24, with the flange 214 of the bolt 21 being received in the nut 24 and urging the blocking pieces 242.

Because the upper portion 24a of the nut 24 has two symmetrical elongated slots 241 formed therein and the nut 24 is elastic, the two claws 24c, 24d of the upper portion 24a of the nut 24 can deform elastically outwardly when the flange 214 of the bolt 21 presses the blocking pieces 242 radially outwardly. When the two claws 24c, 24d have deformed outwardly to the point where the diameter of the imaginary cylindrical surface formed by the inner surfaces of the blocking pieces 242 is greater than the diameter of the flange 214 of the bolt 21, the flange 214 of the bolt 21 can ride past the inner surfaces of the blocking pieces 242 and be received inside the nut 24 by pass though the blocking pieces 242. In addition, due to the slope 248 formed at the connection of each blocking piece 242 and the top surface 247 of the nut 24, the flange 214 of the bolt 21 can enter the space between the blocking pieces 242 smoothly.

Because the diameter of the imaginary cylindrical surface formed by the inner surfaces of the blocking pieces 242 is smaller than the diameter of the flange 214 of the bolt 21, the flange 214 of the bolt 21 can be locked at the bottom of the blocking pieces 242 after the flange 214 of the bolt 21 has been received in the nut 24. This helps prevent the flange 214 from being accidentally pulled upwardly and causing the bolt 21 to separate from the heat conducting plate 12.

Because the elastic element 22 is compressed, the elastic element 22 resiliently pushes the head portion 211 of the bolt 21 upwardly and the heat conducting plate 12 of the heat dissipation device 10 downwardly. Thereby, the upper portion 24a of the nut 24 can be securely received in the groove 125 of the heat conducting plate 12 to contact the heat conducting plate 12, and accidental separation of the nut 24 from the heat conducting plate 12 can be avoided.

In assembly of the electronic device 100, the top holding portion 36 of each fixed leg 32 is firstly placed into the corresponding fixing hole 46 of the circuit board 42. Because the thickness of the circuit board 42 is smaller than the length of the top holding portion 36 of the fixed leg 32, the top holding portion 36 of the fixed leg 32 projects out from a top surface of the circuit board 42. The heat dissipation assembly 110 is located on the circuit board 42, the heat conducting plate 12 contacts the electric element 44, and each nut 24 of the heat dissipation assembly 110 is aligned with the corresponding fixed leg 32 of the back plate 30. Because the distance from the lower portion 24b of the nut 24 to the bottom surface 123 of the heat conducting plate 12 is slightly smaller than the height of the electric element 44, the gap 140 can be formed between the circuit board 42 and the lower portion 24b of the nut 24.

When the head portion 211 of the bolt 21 is pressed downwardly, the connecting portion 213 of the bolt 21 passes through the ring-shaped convex blocking tube 244 to screw into the threaded hole 38 of the fixed leg 32, such that the elastic element 22 is compressed and the flange 214 of the bolt 21 contacts the top surface (not labeled) of the ring-shaped convex blocking tube 244 located at the lower portion 24b of the nut 24. After that, the screwing the bolt 21 is continued until the heat conducting plate 12 and the nut 24 move downwardly and the lower portion 24b of the nut 24 contacts the circuit board 42 firmly. At this position, the heat conducting plate 12 remains biased (pushed downwardly) relative to the circuit board 42 by the elastic element 22. Therefore the heat conducting plate 12 further contacts the electric element 44 located on the circuit board 42 firmly and heat from the electric element 44 can be quickly removed to the heat sink 14 by passing through the heat conducting plate 12. The heat absorbed by the heat sink 14 is then dissipated to ambient air.

Comparing with a typical heat dissipation device, the present heat dissipation assembly 110 contains two nuts 24 placed between the heat conducting plate 12 and the circuit board 42. Significantly, the height (or thickness) of each nut 24 is configured according to that of the electric element 44 located on the circuit board 42. That is, the height of the nut 24 is slightly smaller than the distance between the heat conducting plate 12 and the circuit board 42. Therefore, the deformability of the heat conducting plate 12 and the pressure between the heat conducting plate 12 and the circuit board 42 can be controlled efficiently. Accordingly, damage to the electric element 44 due to excessive pressure from the heat conducting plate 12 can be avoided.

It is to be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A heat dissipation assembly adapted for dissipating heat of an electronic component which is mounted on a circuit board, the heat dissipation assembly comprising:
a heat conducting plate for attaching the electronic component to absorb heat therefrom, the heat conducting plate defining a through hole therein;
a fixing assembly configured for securing the heat conducting plate on the electronic module, the fixing assembly comprising a bolt, an elastic element coiled around the bolt, and a nut; and
a back plate opposite to the heat dissipation device;
a flange being defined at one end of the bolt and received in the nut, the flange of the bolt being configured for moving upwardly and downwardly in the nut; the nut comprising an inner side surface and an outer side surface and also defining a upper portion and an lower portion, the upper portion of the nut having two symmetrical elongated slots extending upwardly from the lower portion of the nut, the upper portion of the nut forming a plurality of blocking pieces perpendicularly extending from the inner side surface of the nut, and the blocking pieces being symmetrically radially placed between the two slots of the nut; the nut being sandwiched between the heat conducting plate and the back plate and being made of elastically plastic; the back plate comprising a hollow fixed leg defined thereon corresponding to the through hole of the heat conducting plate;
the bolt passing through the through hole of the heat conducting plate to connecting the fixed leg of the back plate; the upper portion and the lower portion of the nut being respectively attached to the bottom surface of the heat conducting plate and the electronic module by tension from the elastic element.

2. The heat dissipation assembly as claimed in claim 1, wherein the heat conducting plate is rectangular, and at least two fastening portions respectively extending horizontally outwardly from two opposite edges of the heat conducting plate, the through hole is defined on one corresponding fastening portion.

3. The heat dissipation assembly as claimed in claim 1, wherein the heat conducting plate further defines a groove communicated with the corresponding through hole, a diameter of the groove is greater than a diameter of the through hole, the upper portion of the nut is received in the groove.

4. The heat dissipation assembly as claimed in claim 1, wherein the bolt comprises a head portion, a main body extending from the head portion, and a connecting portion located at one end of the main body opposite to the head portion, the flange is located at the connection of the main body and the connecting portion.

5. The heat dissipation assembly as claimed in claim 4, wherein the connecting portion has outer screw thread defined thereon, the fixed leg of the back plate has a corresponding threaded hole defined therein, the elastic element is coiled around the main body of the bolt, which sandwiched between the heat conducting plate and the head portion of the bolt.

6. The heat dissipation assembly as claimed in claim 1, wherein an inner surface of each blocking piece which faces a center of the nut is a segment of cylindrical face, and all the inner surfaces of the blocking pieces are cooperatively define an imaginary cylindrical surface, a slope is formed at the connection of the inner surface of each blocking piece and a top surface of the nut.

7. The heat dissipation assembly as claimed in claim 1, wherein the lower portion of the nut forms a plurality of connecting pieces extending radially inwardly from the inner side surface of the nut, a ring-shaped convex blocking tube is received in the nut and connecting with all the connecting pieces.

8. The heat dissipation assembly as claimed in claim 1, wherein the fixed leg extends upwardly from the back plate, the fixed leg has a bottom holding portion connected to the back plate and a top holding portion extends upwardly from the bottom holding portion, a diameter of top holding portion is smaller than that of the bottom holding portion.

9. An electronic device comprising an electronic module and a heat dissipation assembly, the electronic module comprising a circuit board and an electric element located on the circuit board, the heat dissipation assembly comprising:
a heat conducting plate for attaching the electronic component to absorb heat therefrom, the heat conducting plate defining a through hole therein;
a fixing assembly configured for securing the heat conducting plate on the electronic module, the fixing assembly comprising a bolt, an elastic element coiled around the bolt, and a nut; and
a back plate opposite to the heat dissipation device;
a flange being defined at one end of the bolt and received in the nut, the flange of the bolt being configured for moving upwardly and downwardly in the nut; the nut comprising an inner side surface and an opposite outer side surface and also defining a upper portion and an opposite lower portion, the upper portion of the nut having two symmetrical elongated slots extending upwardly from the lower portion of the nut, the upper portion of the nut forming a plurality of blocking pieces perpendicularly extending from the inner side surface of the nut, and the blocking pieces being symmetrically radially placed between the two slots of the nut; the nut being sandwiched between the heat conducting plate and the circuit board of the electronic module; the back plate comprising a hollow fixed leg defined thereon corresponding to the through hole of the heat conducting plate;
the bolt passing through the through hole of the heat conducting plate to connecting the fixed leg of the back plate; the upper portion and the lower portion of the nut being respectively attached to the bottom surface of the heat conducting plate and the circuit board of the electronic module by tension from the elastic element.

10. The electronic device as claimed in claim 9, wherein a distance from a terminal end of the lower portion of the nut to the bottom surface of the heat conducting plate is slightly smaller than a height of the electric element of the electronic module.

11. The electronic device as claimed in claim 9, wherein the heat conducting plate is rectangular, and at least two fastening portions respectively extending horizontally outwardly from two opposite edges of the heat conducting plate, the through hole is defined on one corresponding fastening portion.

12. The electronic device as claimed in claim 9, wherein the heat conducting plate further defines a groove communicated with the corresponding through hole, a diameter of the groove is greater than that of the through hole, the upper portion of the nut is received in the groove.

13. The electronic device as claimed in claim 9, wherein the bolt comprises a head portion, a main body extending from the head portion, and a connecting portion located at one end of the main body opposite to the head portion, the flange is located at the connection of the main body and the connecting portion.

14. The electronic device as claimed in claim 13, wherein the connecting portion has outer screw thread defined thereon, the fixed leg of the back plate has a corresponding threaded hole defined therein, the elastic element is coiled around the main body of the bolt, which sandwiched between the heat conducting plate and the head portion of the bolt.

15. The electronic device as claimed in claim 9, wherein an inner surface of each blocking piece which faces a center of the nut is a segment of cylindrical face, and all the inner surfaces of the blocking pieces are cooperatively define an imaginary cylindrical surface, a slope is formed at the connection of the inner surface of each blocking piece and a top surface of the nut.

16. The electronic device as claimed in claim 9, wherein the lower portion of the nut forms a plurality of connecting pieces extending radially inwardly from the inner side surface of the nut, a ring-shaped convex blocking tube is received in the nut and connecting with all the connecting pieces.

17. The electronic device as claimed in claim 9, wherein the fixed leg extends upwardly from the back plate, the fixed leg has a bottom holding portion connected to the back plate and a top holding portion extends upwardly from the bottom holding portion, a diameter of top holding portion is smaller than that of the bottom holding portion.
